(19) United States
(12) Patent Application Publication
(10) Pub. No.: US 2005/0079644 A1
(43) Pub. Date: Apr. 14, 2005

(54) Method for manufacturing electro-optical panel

(75) Inventor: Kazuaki Sakurada, Suwa-shi (JP)

Correspondence Address: SHINJYU GLOBAL IP COUNSELORS, LLP, 1233 20TH STREET, NW, SUITE 700, WASHINGTON, DC, 20036-2680, US

(73) Assignee: Seiko Epson Corporation, Shinjuku-ku (JP)

(21) Appl. No.: 10/794,183

(22) Filed: Mar. 8, 2004

(30) Foreign Application Priority Data
Mar. 13, 2003 (JP) 2003-068330
Feb. 17, 2004 (JP) 2004-040067

(51) Int. Cl. H01L 21/00

(52) U.S. Cl. 438/26

(57) ABSTRACT

A method for manufacturing an electro-optical panel has a filter formation step, a surface modification step, a protective film material application step, and a protective film formation step. A color filter is formed on a substrate in the filter formation step. The surface of the color filter is modified in the surface modification step. Droplets of protective film material containing a resin and a solvent are discharged and applied to the color filter in the protective film material application step. The viscosity of the protective film material used is 1 to 20 mPa.s at 20° C., and the surface tension is 20 to 70 mN/m at 20° C. The solvent is dried and a color filter protective film for protecting the color filter is formed in the protective film formation step.

### BACKGROUND OF THE INVENTION

1. Field of the Invention

The present invention relates to a method for manufacturing an electro-optical panel, and particularly relates to a method for manufacturing an electro-optical panel having a color filter protective film.

2. Background Information

Liquid crystal panels and other electro-optical panels capable of displaying color have a substrate with a color filter to extract selectively light with a specific wavelength from the white light of a light source. Color filters are generally formed from a resin colored with R (red), G (green), and B (blue) pigments. A color filter protective film is then formed on the color filter for the purpose of protecting the color filter and smoothing the surface of the color filter.

Conventionally, color filter protective films are made by thin film fabrication methods typified by spin coating, but such methods have been wasteful in that 90 percent or greater of the color filter protective film is discarded. Also, since a color filter protective film material in liquid form is formed into a thin film by centrifugal force in spin coating, the color filter protective film material adheres to the back surface of the color filter substrate, and a step for washing the back surface of the color filter substrate has been required. This has been a cause of decreased productivity. Furthermore, since a color filter protective film material in liquid form is formed into a thin film by centrifugal force in spin coating, it has been difficult to adapt this technique to a color filter substrate with large dimensions.

In view of this, techniques have recently been proposed for applying color filter protective film materials by inkjet (droplet discharge) methods, as disclosed, for example, in Patent Literature 1 and 2.

Inkjet methods waste hardly any material because the color filter protective film material is discharged from a nozzle to the necessary location. Also, there is no need to wash the back surface of the color filter substrate because the color filter protective film material is accurately discharged to a specific position on the color filter substrate. Furthermore, it is possible to adapt this technique to a color filter substrate with large dimensions if the scanning range of the inkjet head is increased (see JP-A 9-329707 and 2002-189120).

Depending on the type of liquid to be discharged, however, inkjet methods are prone to unsatisfactory discharges and clogging of the nozzle, because droplets are discharged from a small nozzle at a high frequency of 10 to 20 Hz. Particularly, conditions are severe for discharging a color filter protective film material made of a resin dissolved in a solvent, and the techniques disclosed in the above-mentioned Patent Literature 1 and 2 are prone to insufficient supply of the color filter protective film material in the inkjet head and clogging of the nozzle. Thus, stabilized discharge is difficult to achieve.

It will be clear to those skilled in the art from the disclosure of the present invention that an improved method for manufacturing an electro-optical panel is necessary because of the above-mentioned considerations. The present invention meets the requirements of these conventional technologies as well as other requirements, which will be apparent to those skilled in the art from the disclosure hereinbelow.

### SUMMARY OF THE INVENTION

An object of this invention is to provide a method for manufacturing an electro-optical panel that can form high-quality color filter protective films.

The method for manufacturing an electro-optical panel relating to this invention includes a filter formation step, a surface modification step, a protective film material application step, and a protective film formation step. A color filter is formed on a substrate in the filter formation step. The surface of the color filter is modified in the surface modification step. Droplets of protective film material containing a resin and a solvent are discharged and applied to a color filter in the protective film material application step. The viscosity of the protective film material used is 1 to 20 mPa.s at 20° C., and the surface tension is 20 to 70 mN/m at 20° C. The solvent is dried and the color filter protective film for protecting the color filter is formed in the protective film formation step.

The objectives, characteristics, merits, and other attributes of the present invention described above shall be clear to those skilled in the art from the description of the invention hereinbelow. The description of the invention and the accompanying diagrams disclose the preferred embodiments of the present invention

### BRIEF DESCRIPTION OF THE DRAWINGS

FIG. 1 is a partial cross-sectional view showing a structure of an electro-optical panel according to the present invention;

FIG. 2 is a partial cross-sectional view showing a color filter substrate according to the present invention;

FIG. 3-1 is an explanatory diagram showing a method for manufacturing the electro-optical panel and an electronic device according to the present invention;

FIG. 3-2 is an explanatory diagram showing the method for manufacturing the electro-optical panel and the electronic device according to the present invention;

FIG. 3-3 is an explanatory diagram showing the method for manufacturing the electro-optical panel and the electronic device according to the present invention;

FIG. 3-4 is an explanatory diagram showing the method for manufacturing the electro-optical panel and the electronic device according to the present invention;

FIG. 3-5 is an explanatory diagram showing the method for manufacturing the electro-optical panel and the electronic device according to the present invention;

FIG. 3-6 is an explanatory diagram showing the method for manufacturing the electro-optical panel and the electronic device according to the present invention;

FIG. 3-7 is an explanatory diagram showing the method for manufacturing the electro-optical panel and the electronic device according to the present invention;

FIG. 4 is a flowchart showing the method for manufacturing the electro-optical panel and the electronic device according to the present invention;

FIG. 5-1 is an explanatory diagram showing a droplet discharge device according to the present invention;

FIG. 5-2 is an explanatory diagram showing the droplet discharge device according to the present invention;

FIG. 5-3 is an explanatory diagram showing the droplet discharge device according to the present invention;

FIG. 5-4 is an explanatory diagram showing the droplet discharge device according to the present invention;

FIG. 5-5 is an explanatory diagram showing the droplet discharge device according to the present invention;

FIG. 6-1 is a plan view showing a state wherein protective film material has been applied;

FIG. 6-2 is a plan view showing a state wherein the protective film material has been applied;

FIG. 7-1 is an explanatory diagram showing an application pattern of the protective film material;

FIG. 7-2 is an explanatory diagram showing the application pattern of the protective film material;

FIG. 8 is a flowchart showing the method for manufacturing an electro-optical panel and an electronic device according to an Embodiment 2;

FIG. 9 is an explanatory diagram showing a CF substrate of the electro-optical panel according to the Embodiment 2;

FIG. 10-1 is an explanatory diagram showing a droplet discharge device according to an Embodiment 3;

FIG. 10-2 is an explanatory diagram showing the droplet discharge device according to the Embodiment 3;

FIG. 10-3 is an explanatory diagram showing the droplet discharge device relating to the Embodiment 3;

FIG. 11 is a perspective view showing a CF protective film formation device according to an Embodiment 4;

FIG. 12 is a schematic structural perspective view showing a vicinity of a drawing part;

FIG. 13-1 is a perspective view of a large standard plate as seen from the nozzle of the droplet discharge head;

FIG. 13-2 is an enlarged view of a single droplet discharge head;

FIG. 13-3 is a plan view of a droplet discharge head as seen from the nozzle;

FIG. 14-1 is a perspective view showing the internal structure of the droplet discharge head; and

FIG. 14-2 is a cross-sectional view showing the internal structure of the droplet discharge head.

### DESCRIPTION OF THE PREFERRED EMBODIMENTS

Embodiments of the present invention will now be described with reference to the drawings. As will be apparent from the disclosure of the present invention to those skilled in the art, the description of the invention embodiments is intended solely to illustrate the present invention and should not be construed as limiting the scope of the present invention, which is defined by the claims described below or by equivalent claims thereof.

The preferred embodiments of the present invention will now be described with reference to the drawings.

Examples of the electro-optical panel relating to the present invention include, for example, a liquid crystal display panel, a DMD (digital micromirror device) display panel, and an organic EL (electroluminescence) display panel.

### Embodiment 1

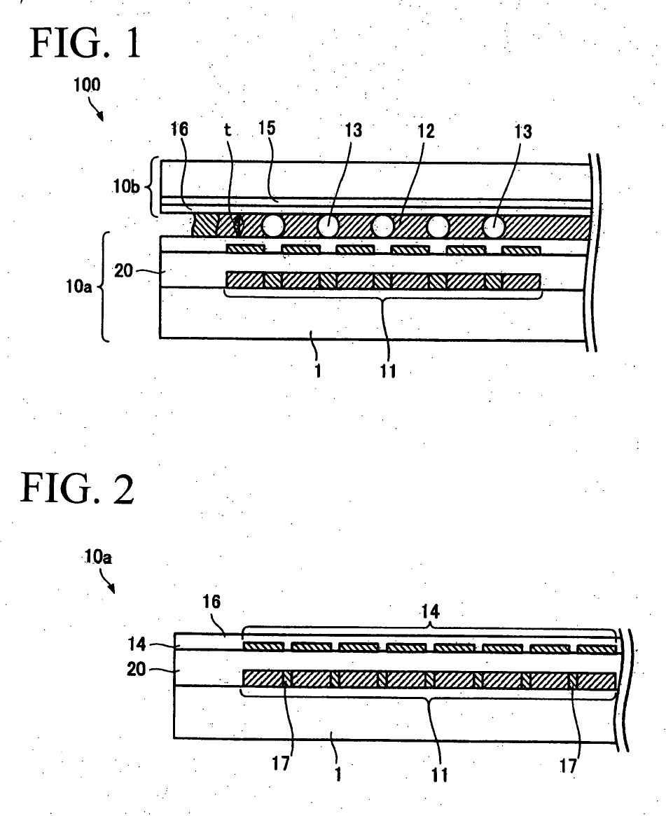

FIG. 1 is a partial cross-sectional view showing the structure of the electro-optical panel relating to the present invention. This electro-optical panel 100 is such that a protective film in liquid form whose viscosity and surface tension have been adjusted to a specific range is applied by a droplet discharge system to a color filter substrate on which a color filter is formed.

The electro-optical panel 100 is made of liquid crystal 12 sealed between a color filter substrate 10a wherein a color filter 11 is formed on the surface of a substrate 1, and an opposing substrate 10b disposed opposite thereto. Spacers 13 are disposed between the color filter substrate 10a and the opposing substrate 10b, and the gap t between the substrates is virtually constant over the entire surface.

FIG. 2 is a partial cross-sectional view showing the color filter substrate relating to the present invention. The color filter 11 is formed on the side of the color filter substrate 10a that faces the opposing substrate 10b. A block matrix 17 is formed within the color filter 11. A color filter protective film 20 (hereinafter “CF protective film”) is formed on the color filter 11 by the protective film material relating to the present invention. Thus, the color filter 11 formed on the substrate 1 is protected.

Also, an ITO (indium tin oxide) electrode 14 and an orientation film 16 are formed on the CF protective film 20. The CF protective film 20 has a function to protect the color filter 11 from high temperatures when the ITO electrode 14 is formed, and a function to level the irregularities within the color filter 11 and to suppressi burnouts in the ITO electrode 14 and rubbing defects in the orientation film 16.

A plurality of electrodes 15 is formed in a stripe configuration on the inner surface of the opposing substrate 10b to be perpendicular to the electrodes next to the color filter 11, and the orientation film 16 is formed on these electrodes 15. The color filter 11 is disposed at a position that intersects the ITO electrode 14 and the electrodes 15 on the respective substrates. An electrode 39 is also formed from ITO or another such transparent conductive material. A method for manufacturing an electro-optical panel by forming a CF protective film, and an electronic device by manufacturing the electro-optical panel will now be described.

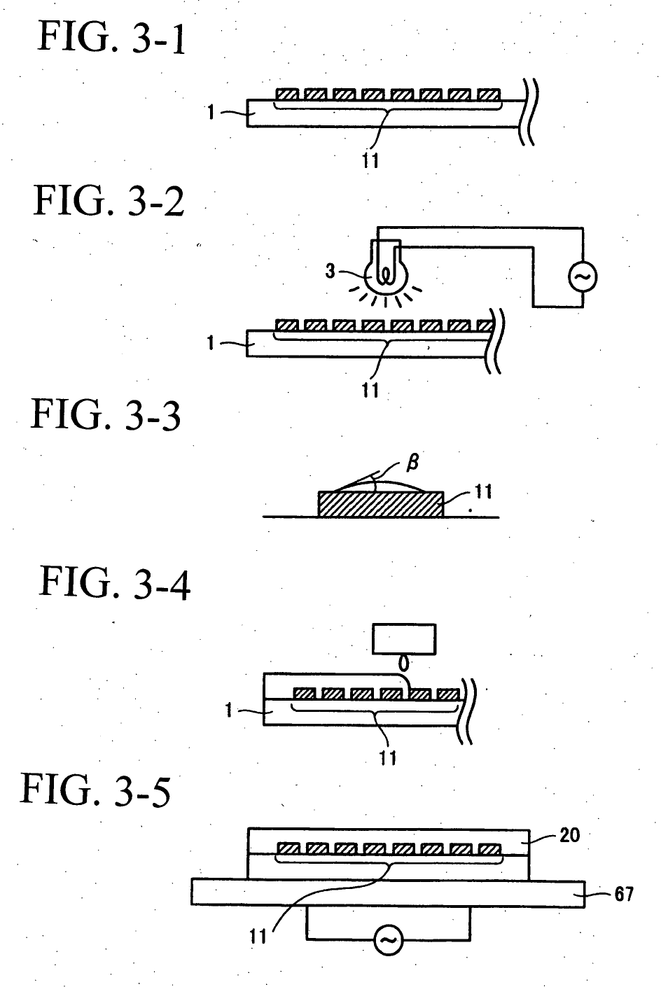

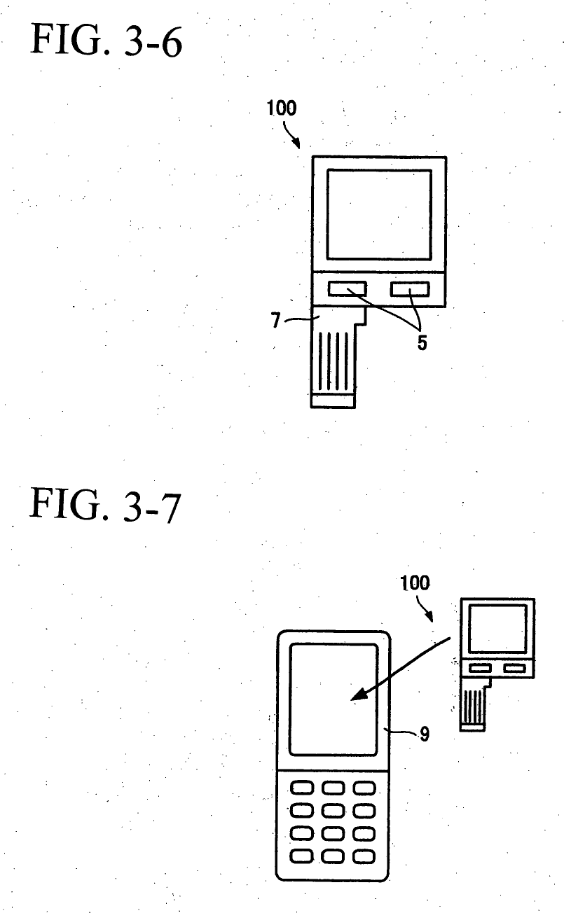

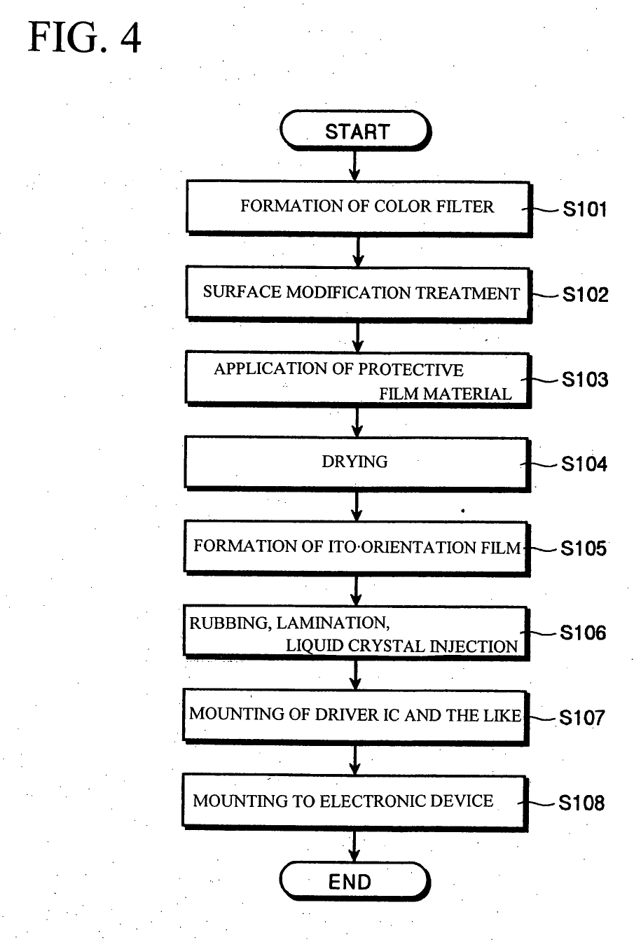

FIGS. 3-1 through 3-7 are explanatory diagrams showing the method for manufacturing the electro-optical panel and an electronic device relating to the present invention. FIG. 4 is a flowchart showing the method for manufacturing the electro-optical panel and an electronic device relating to the present invention. FIGS. 5-1 through 5-5 are explanatory diagrams showing the droplet discharge device relating to the present invention. First, the color filter 11 is formed on the substrate 1 as shown in FIG. 3-1 by photolithography or by droplet discharge with an inkjet, plunger, or the like (step S101).

Next, to improve the wettability of the color filter 11 and the protective film material in liquid form applied thereon, the color filter 11 is subjected to a surface modification treatment (step S102) as shown in FIG. 3-2, thus improving the wettability of the protective film material. The reason is that if the wettability were poor, the protective film material would tend to form into droplets, and hence would fail to be uniformly applied to the color filter 11. Another reason is the danger that the protective film material may not easily penetrate within the color filter 11, foam may be produced in this portion, and the display image quality of the electro-optical panel may be reduced. The surface modification treatment is performed in the present embodiment by emitting ultraviolet light from a UV lamp 3, but oxygen plasma treatment can also be performed. Oxygen plasma treatment is particularly preferable in the sense that the quality of the CF protective film 20 is increased because the residue on the color filter 11 can be removed.

The wettability of the color filter 11 and the protective film material in liquid form applied thereon can be determined by the angle of contact β of the protective film material with the color filter 11 (see FIG. 3-3). In the method for manufacturing the electro-optical panel relating to the present invention, the angle of contact β is preferably 10 degrees or less. In this range, the protective film material can sufficiently penetrate within the color filter 11, and the protective film material can be formed on the color filter 11 with a uniform thickness, so a CF protective film 20 of high quality can be formed.

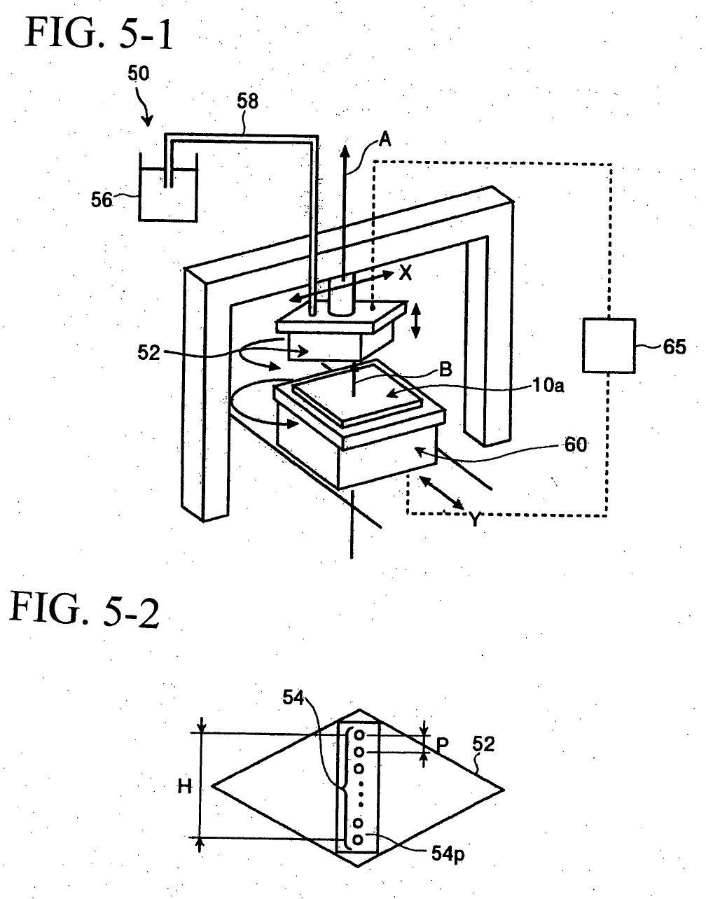

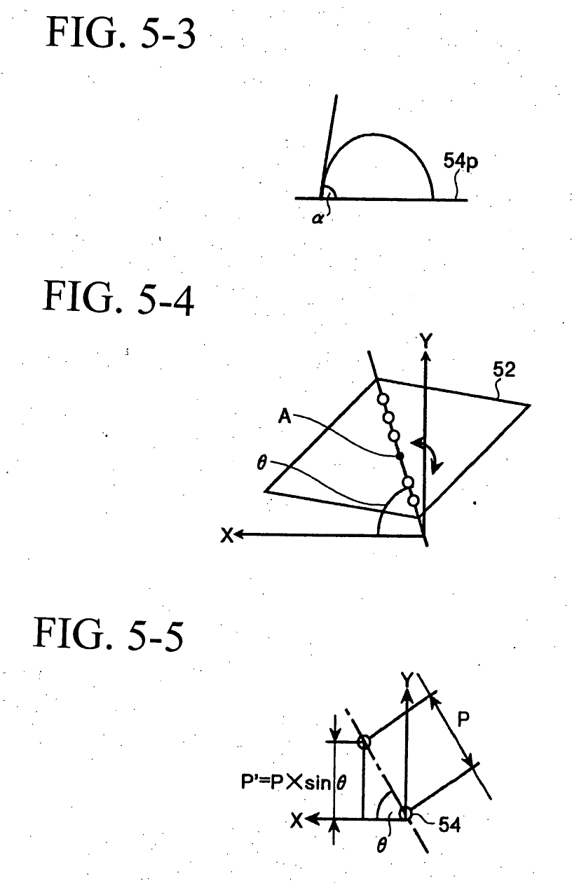

When the surface modification treatment is complete, the protective film material in liquid form is applied to the color filter 11 by droplet discharge as shown in FIG. 3-4 (step S103). The application of the protective film material will now be described using FIG. 5. Ink jetting is used as the droplet discharge in the present invention. A droplet discharge device 50 has a droplet discharge head 52 and a stage 60. The protective film material in liquid form is fed to the droplet discharge head 52 from a tank 56 via a supply tube 58.

The droplet discharge head 52 is made of a plurality of nozzles 54 arranged within an alignment width H at a constant pitch P, as shown in FIG. 5-2. Also, each nozzle 54 has a piezoelement, and droplets of the protective film material are discharged from the nozzles 54 according to a command from a control device 65. The amount in which the protective film material is discharged from the nozzles 54 can also be varied by changing the drive pulse supplied to the piezoelement. A personal computer or workstation may be used as the control device 65.

The droplet discharge head 52 is also capable of rotating around a rotation axis A as the center of rotation, wherein the rotation axis A is perpendicular to the center of the head. When the droplet discharge head 52 is rotated around the rotation axis A and an angle θ is assigned between the alignment direction of the nozzles 54 and the X direction, the apparent pitch of the nozzles 54 can be denoted by P′=P×Sin θ, as shown in FIGS. 5-4 and 5-5. Thus, the pitch of the nozzles 54 can be varied according to the coated area of the color filter substrate 10a, the type of protective film material, and other such coating conditions. The color filter substrate 10a is mounted on the stage 60. The stage 60 can move in the Y direction (auxiliary scanning direction) and rotate around a rotation axis B as the center of rotation, wherein the rotation axis B is perpendicular to the center of the stage 60.

The droplet discharge head 52 moves back and forth in the X direction in the diagram (main scanning direction) while droplets of the protective film material are discharged on the color filter substrate 10a within the alignment width H of the nozzles 54. Once the protective film material has been applied in a single scan, the stage 60 moves in the Y direction over a distance equal to the alignment width H of the nozzles 54, and the droplet discharge head 52 discharges the protective film material on the next area. The operation of the droplet discharge head 52, the discharge of the nozzles 54, and the operation of the stage 60 are controlled by the control device 65. It is simple to vary the application pattern according to the coated area of the color filter substrate 10a, the type of protective film material, and other such coating conditions if these operating patterns are programmed in advance. All areas of the color filter substrate 10a can be coated with the protective film material by repeating the above-mentioned operation. Similarly, it is possible to discharge the protective film material from the droplet discharge head 52 when the stage 60 moves in the Y direction, and then to move the droplet discharge head 52 in the X direction over the alignment width H and to discharge the protective film material on the next area.

FIGS. 6-1 and 6-2 are plan views showing a state wherein the protective film material has been applied. Droplets of the protective film material are applied to the color filter substrate 10a in intervals of 10 μm in the main scanning direction (X direction) and 140 μm in the auxiliary scanning direction (Y direction). The interval y between the droplets in the auxiliary scanning direction is the same as the pitch P of the nozzles 54 (140 μm in Embodiment 1). The interval x between the droplets in the main scanning direction depends on the scanning rate and discharge frequency of the droplet discharge head 52.

The mass m of a single drop of the protective film material is 20 ng in Embodiment 1, and a CF protective film 20 with a film thickness s of 1 μm can be formed at the above-mentioned droplet interval after the solvent of the protective film material is volatilized. If the same protective film material is used, the film thickness of the CF protective film 20 can be controlled according to the mass of one drop of the protective film material and the droplet intervals x and y in the main and auxiliary scanning directions on the color filter substrate 10a. Specifically, the film thickness s of the CF protective film 20 can be determined with the values m, x, and y as parameters. In the present invention, it is possible to control all of these parameters, so the film thickness s can be controlled by adjusting at least one of these parameters.

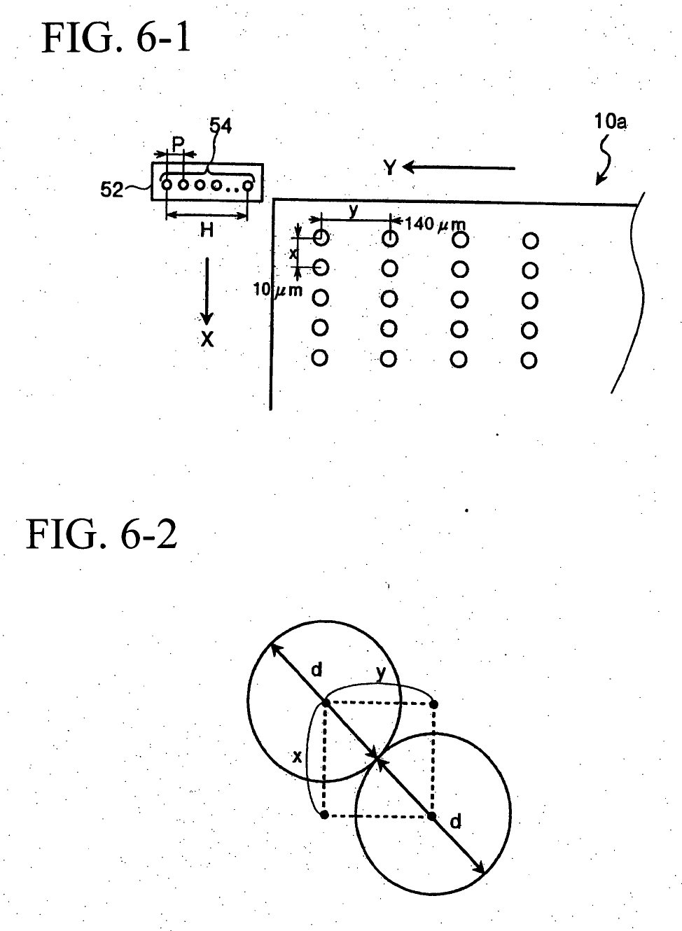

When the mass m of one drop of the protective film material is 20 ng, the protective film material on the color filter substrate 10a expands to a circular shape with a diameter of about 200 μm. Therefore, all the adjacent droplets of the protective film material join together into as a whole in the case of the above-mentioned values x and y. The droplets of the protective film material fail to join together when x and y both exceed d×√2/2, where d is the diameter of the protective film material on the color filter substrate 10a, as shown in FIG. 6-2. Therefore, the droplet intervals of the protective film material on the color filter substrate 10a must be kept within a range wherein x and y both do not exceed d×√2/2. Specifically, four droplets disposed next to each other to form a square shape on the color filter substrate 10a must all be in overlapping locations.

In this case, the interval y between the droplets in the auxiliary scanning direction depends on the pitch P of the nozzles 54, so the alignment width H of the nozzles 54 decreases with reduced pitch if the number of nozzles remains the same. Therefore, reducing the pitch of the nozzles 54 allows the application rate of the protective film material to be reduced as long as the number of nozzles is not increased. In the present invention, x and y are both equal to d×√2/2 or less, so the droplets of the protective film material on the color filter substrate 10a can be joined together without varying the pitch P of the nozzles 54 in the main scanning direction even if y is equal to 14 times the value of x. Thus, a CF protective film 20 can be formed without reducing the application rate of the protective film material.

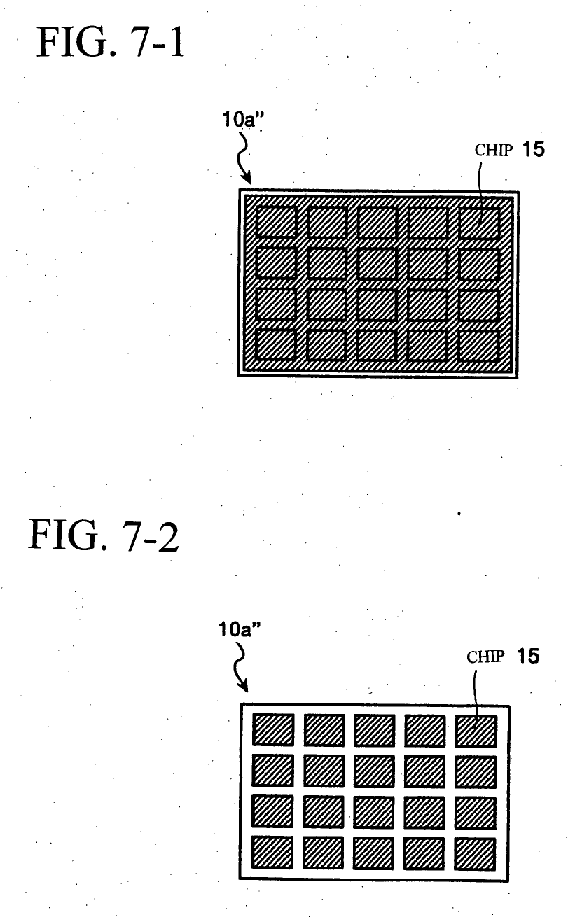

FIGS. 7-1 and 7-2 are explanatory diagrams showing the application pattern of the protective film material. The application pattern of the protective film material will now be described using FIGS. 7-1 and 7-2. FIG. 7-1 shows an example wherein the protective film material is applied to the entire surface of the color filter substrate 10a″, which is the matrix, and FIG. 7-2 shows an example wherein the protective film material is applied to the area on which the color filter 11 is formed, or, specifically, to part of the color filter substrate 10a″. In the application example shown in FIG. 7-2, there is less waste of the protective film material because the protective film material is applied only to the necessary areas. In the application example shown in FIG. 7-2, the protective film material is applied to the entire surface of the color filter substrate 10a″. The CF protective film of uniform thickness can therefore be formed with greater ease on a chip 15 with smaller dimensions than the color filter substrate 10a″. Any application pattern can be selected with consideration for the manufacturing costs. The chip 15 herein constitutes one electro-optical panel. The protective film material can be easily applied in accordance with these application patterns by inputting the control data of the droplet discharge head 52 and stage 60 that correspond to these application patterns to the control device 65.

In droplet discharge, droplets of the protective film material must be discharged in a stable manner from the nozzles 54. Therefore, the protective film material relating to the present invention is adjusted to have physical property values suitable for droplet discharge. Specifically, the viscosity at 20° C. is 1 to 20 mPa.s, and, similarly, the surface tension at 20° C. is 20 to 70 mN/m. In these ranges, the protective film material can be supplied in a stable manner to the nozzles 54, and the meniscus of the protective film material solution at the outlet of the nozzles 54 is also stabilized. Thus, droplets of the protective film material are discharged from the nozzles 54 in a stable manner and a high-quality CF protective film 20 can be formed. Also, the discharge capabilities of the piezoelement are not exceeded because the energy required for droplet discharge does not increase excessively as long as these ranges of viscosities and surface tensions are maintained

Furthermore, it is more preferable that the viscosity at 20° C. is 4 to 8 mPa.s, and the surface tension at 20° C. is 25 to 35 mN/m. In these ranges, the protective film material can be supplied to the nozzles 54 in a more stable manner and the meniscus of the protective film material solution in the outlet of the nozzles 54 is stabilized. Thus, droplets of the protective film material are discharged from the nozzles 54 in a more stable manner and a high-quality CF protective film 20 can be formed.

The protective film material relating to the present invention will now be described. The protective film material contains at least one of the following: an acrylic resin, an epoxy resin, an imide resin, and a fluorine resin. After the solvent in the protective film material is volatilized, these resins form the CF protective film 20 of the color filter 11. Also, the solvent of the resin contains at least one of the following: glycerin, diethylene glycol, methanol, ethanol, water, 1,3-dimethyl-2-imidazolidinone, ethoxyethanol, N,N-dimethyl formamide, N-methyl-2-pyrrolidone, ethylene glycol monomethyl ether acetate, propylene glycol monomethyl ether acetate, ethyl lactate, 3-methoxy methyl propionate, 3-ethoxy ethyl propionate, butyl acetate, 2-heptanone, propylene glycol monomethyl ether, γ-butyrolactone, diethylene acetate glycol monobutyl ether, diethylene glycol methyl ether, and diethylene glycol methylethyl ether. The viscosity and surface tension are adjusted by the mixture ratio of the resin and the solvent.

A solvent with a high boiling point is preferred from among these solvents. The protective film material does not immediately dry when applied to the color filter substrate 10a because a solvent with a high boiling point is slow to dry. As a result, a sufficient amount of time can be ensured for the thickness of the protective film material on the color filter substrate 10a to become uniform, so a CF protective film 20 of uniform thickness can be obtained. Also, nozzle clogging due to precipitation of the solids near the nozzles can be prevented. To obtain such effects, the boiling point of the solvent is preferably kept at 180° C. or greater, and more preferably 200° C. or greater, in order to form a CF protective film 20 with a more uniform thickness. Of the above-mentioned solvents, diethylene acetate glycol monobutyl ether is preferred for the method for manufacturing an electro-optical panel relating to the present invention because it has a boiling point of 246° C. Also, the boiling point can be adjusted to the desired level by combining the above-mentioned solvents.

Furthermore, the contact angle α (see FIGS. 5-2 and 5-3) between the protective film material and the nozzle plate 54p, which is a flat member, is preferably in a range of 30 to 170 degrees. When the contact angle a between the protective film material and the nozzle plate 54p is too small, the protective film material is shifted toward the nozzle plate 54p when the protective film material is discharged from the nozzles 54. As a result, the location at which the droplets of the protective film material adhere to the color filter substrate 10a is misaligned and the film thickness of the CF protective film 20 may not be uniform. If the contact angle α is in the above-mentioned range, the protective film material does not shift toward the nozzle plate 54p and the droplets of the protective film material adhere to a specific location on the color filter substrate 10a. The above-mentioned contact angle α is preferably 50 degrees or greater, and is more preferably 80 degrees or greater, for the droplets of the protective film material to adhere to a specific location in a more stable manner.

The nozzle plate 54p is subjected to a fluid repellent treatment, for example, to keep the contact angle a between the protective film material and the nozzle plate 54p in the above-mentioned range. The fluid repellent treatment is performed by coating the nozzle plate 54p with a fluid repellent material. A fluorine-containing silane-coupling agent can be used as such a material. Specifically, trifluoropropyl trichlorosilane is used as a fluid repellent material, and the nozzle plate 54p is coated with a solution thereof diluted to a concentration of 0.1% with ethanol as a solvent. In addition to trifluoropropyl trichlorosilane, it is also possible to use heptadecafluorodecyl trichlorosilane, trifluoropropyl trimethoxysilane, heptadecatrifluorodecyl trimethoxysilane, or another such fluorine-containing silane-coupling agent can be used as a surface-modifying agent. The term “fluid-repellent” refers to the repelling of the protective film material by the nozzle plate 54p, and any treatment that reduces the wettability between the two can be considered a fluid repellent treatment.

When applied to the color filter substrate 10a, the protective film material is dried in order to volatilize the solvent in the protective film material (step S104). In the present, the substrate 1 on which the droplets of the protective film material are applied is mounted on a hot plate 67, and the solvent in the protective film material is volatilized as shown in FIG. 3-5. At this point, drying is preferably performed for a certain amount of time at a relatively low temperature in order to smooth the surface of the CF protective film 20. Specifically, a period of five minutes or greater is preferably needed at 70° C. or less. To further smooth the surface of the CF protective film 20, 10 minutes or greater at 50° C. or less is preferred, and one hour or more at 30° C. or less is more preferred. The drying method is not limited to the hot plate 67, and drying may also be performed by heating with an infrared heater or in an oven. Thus, the solvent in the protective film material is volatilized and the CF protective film 20 is formed on the color filter substrate 10a.

Next, the ITO electrode 14 and the orientation film 16 are formed on the CF protective film 20 (step S105). Then, a step to rub the orientation film 16, a step to laminate the color filter substrate 10a and the opposing substrate 10b, and a step to inject the liquid crystal are performed (step S106), and the electro-optical panel 100 is completed. A harness or FPC (flexible printed circuit) 7, or a driver IC 5 is mounted on the completed electro-optical panel 100 (step S107) as shown in FIG. 3-6. The resulting assembly is then mounted on a portable phone, PDA, or other such electronic device 9 as shown in FIG. 3-7, and these electronic devices are completed (step S108).

According to Embodiment 1 of the present invention above, the viscosity and surface tension of the protective film material are kept in a specific range, so there are no discharge failures due to increased wetting of the protective film material or nozzle clogging or the like, and droplets of the protective film material can be discharged from the nozzles in a stable manner. Also, in the present invention, the amount of the protective film material used can be reduced compared with conventional spin coating because a CF protective film is formed using droplet discharge. Furthermore, since there is no need to perform a step for washing the back surface of the color filter substrate, the time for manufacturing the electro-optical panel and the electro-optical device can be shortened, and there is also no need for a cleaning solution.

### Embodiment 2

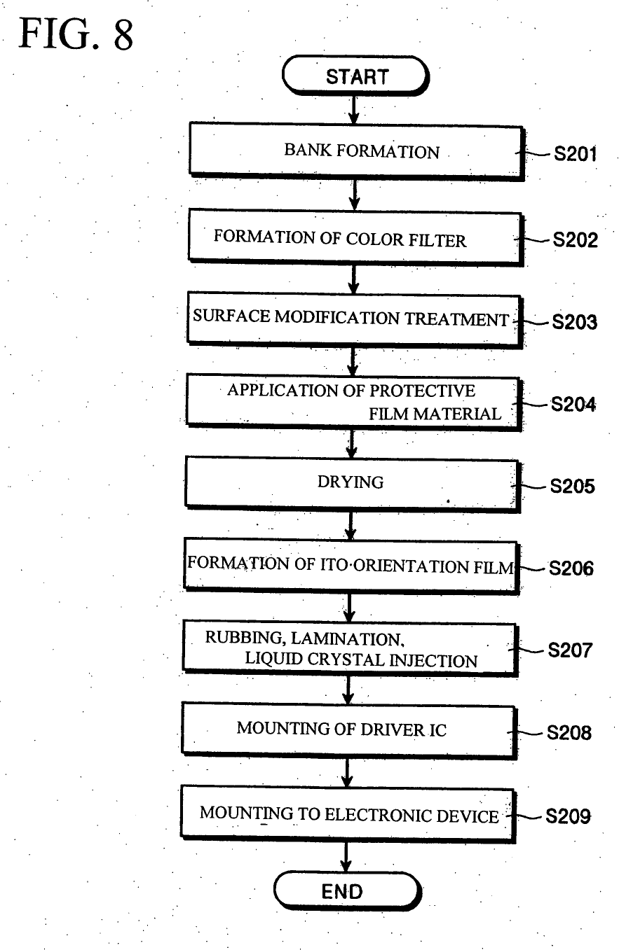

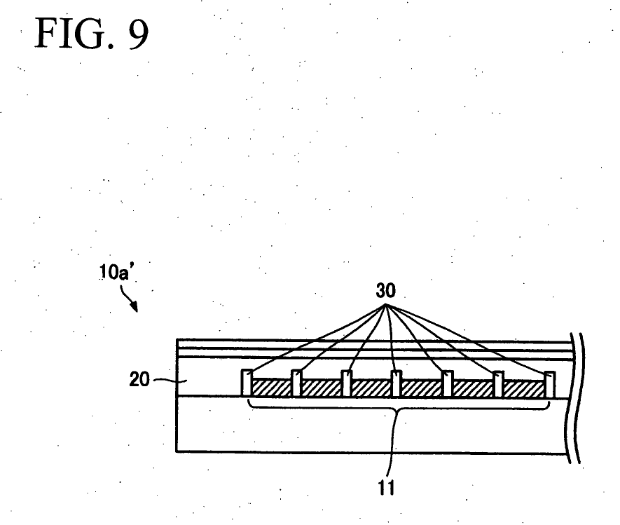

FIG. 8 is a flowchart showing the method for manufacturing the electro-optical panel and an electronic device relating to Embodiment 2. FIG. 9 is an explanatory diagram showing the CF substrate of the electro-optical panel relating to Embodiment 2.

The method for manufacturing the electro-optical panel and the electronic device relating to Embodiment 2 differs in that banks (barrier walls) are provided, a color filter 11 is formed therein, and a CF protective film 20 is then formed on the color filter 11. Otherwise the configuration is the same as in Embodiment 1, so redundant descriptions are omitted and the same structural elements are denoted by the same symbols.

First, banks 30 are formed on the substrate 1 (step S201), and sections for forming the color filter 11 are formed. The banks 30 are formed by applying an ink-repellent resin in a specific thickness by spin coating, for example, and then partitioning the thin resin film into a lattice configuration by using photolithography or another such patterning technique. The term “ink-repellent” refers to the property of low wettability by the filter ink in which a colored resin is dissolved in a solvent.

The banks can also have a layered configuration. For example, a first bank layer made from inorganic material can be formed, and a second bank layer made from organic material can be formed thereon. For example, a material composed of SiO₂, Cr, or the like can be used for the first bank layer. A material composed of acryl, polyimide, or the like can be used for the second bank layer. It is also possible to form layers of different organic materials.

Next, the color filter 11 is formed (step S202). The color filter 11 can be formed by coating the insides of the sections separated off by the banks 30 with a color filter ink in which a colored resin is dissolved in a solvent, using a droplet discharge system. The filter ink can be applied inside the sections with the aid of the banks 30 formed by the ink-repellent resin, even when the color filter ink is discharged somewhat out of alignment towards the inside of the sections separated off by the banks 30. The droplet discharge device 50 (see FIG. 5) relating to Embodiment 1 can be used for such droplet discharge.

When the color filter 11 is formed on the substrate 1, the color filter 11 is subjected to a surface modification treatment (step S203). The reason for this is as explained in Embodiment 1. The portion with the banks 30 is subjected to a thorough surface modification treatment to form the CF protective film 20 with a uniform thickness because the banks 30 are formed from an ink-repellent resin. After the surface modification treatment, the color filter 11 is coated with the protective film material by droplet discharge (step S204). After the protective film material is applied, drying is performed (step S205), an ITO and an orientation film are formed (step S206), and the color filter substrate 10a′ is completed. Descriptions of the subsequent steps are omitted because they are the same as steps S106 through S108 of the method for manufacturing an electro-optical panel and an electronic device relating to Embodiment 1.

Thus, the present invention can be applied even to an electro-optical panel on which a color filter 11 is formed in sections separated off by banks. Therefore, there are no discharge failures due to increased wetting of the protective film material or nozzle clogging, and droplets of the protective film material can be discharged from the nozzles in a stable manner. Also, the amount of the protective film material used can be reduced compared with conventional spin coating, and the time for manufacturing the electro-optical panel and the electro-optical device can be shortened since there is no need to perform a step for washing the back surface of the color filter substrate, and there is also no need for a cleaning solution.

### Embodiment 3

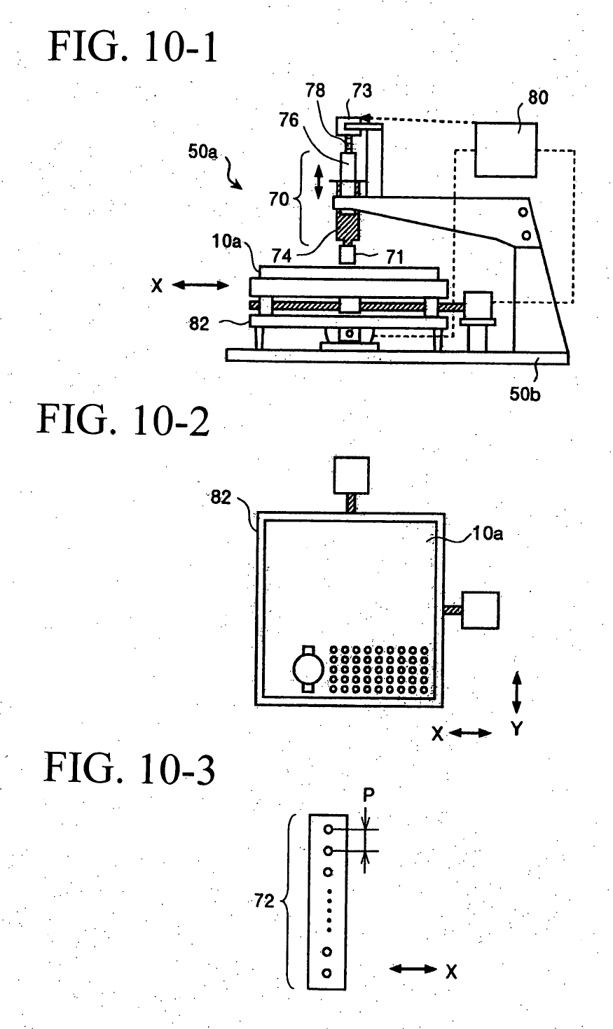

FIGS. 10-1 through 10-3 are explanatory diagrams showing the droplet discharge device relating to Embodiment 3. The droplet discharge device 50a is such that a plunger is used for droplet discharge. The plunger 70 is configured from a cylinder 74 with a nozzle head 71 on the tip, and a piston 76 inserted therein. The nozzle head 71 is made of a plurality of nozzles 72 arranged at a specific pitch P as shown in FIG. 10-2. Also, the protective film material accumulates in the cylinder 74, and the piston 76 is moved toward the nozzle head 71, whereby the protective film material is discharged from the nozzles 72.

A feed screw 78 is mounted on the piston 76, and rotating a stepping motor 73 on which the feed screw 78 is mounted causes the piston 76 to move toward the nozzle head 71. The stepping motor 73 is rotated a specific number of rotations according to a command from a control part 80. When the feed screw 78 rotates, the piston 76 moves the distance of the pitch PS of the feed screw 78. Also, it is possible to control the discharge amount of the protective film material according to the number of rotations of the feed screw 78 because of a proportional relation between the moving distance of the piston 76 and the discharge amount of the protective film material.

The color filter substrate 10a is mounted on an X-Y stage 82 and is capable of moving in the X and Y directions. The plunger 70 is mounted on the device main body 50b such that the direction of alignment of the nozzles 72 is parallel to the Y direction. When the CF protective film 20 is formed on the color filter substrate 10a, first the X-Y stage is moved, and the starting location for applying the protective film material on the color filter substrate 10a is determined. Next, a specific amount of the protective film material is applied to a light-distributing substrate from the nozzles 72 by rotating the stepping motor 73 to a specific degree according to a command from the control part 80.

Next, the X-Y stage 82 is moved a specific width in the X direction according to a command from the control part 80, and a specific amount of the protective film material is similarly applied to the light-distributing substrate from the nozzles 72. When this procedure is repeated along the width of the color filter substrate 10a, the protective film material can be applied across the alignment width H of the nozzles 72 in the width direction (X direction) of the color filter substrate 10a. Next, the X-Y stage 82 is moved in the Y direction over a distance equal to the alignment width H of the nozzles 72 according to a command from the control part 80, and the protective film material is applied in the next line in the Y direction by repeating the above-mentioned procedure. The CF protective film 20 can be formed on the color filter substrate 10a by repeating this procedure in the Y direction of the color filter substrate 10a. Thus, the CF protective film 20 can be formed on the color filter substrate 10a in the same manner as with ink jetting even when a plunger is used for droplet discharge.

### Embodiment 4

In the droplet discharge device 50 relating to Embodiment 1 already described, the droplet discharge head 52 as such moves back and forth above the substrate, the substrate is transported in a direction perpendicular to the direction of movement of the droplet discharge head 52, and a protective film is formed on the color filter. In Embodiment 4, a head with an expanded area of droplet application is mounted by lining up a plurality of heads, and a CF protective film is formed into a pattern while the substrate is transported.

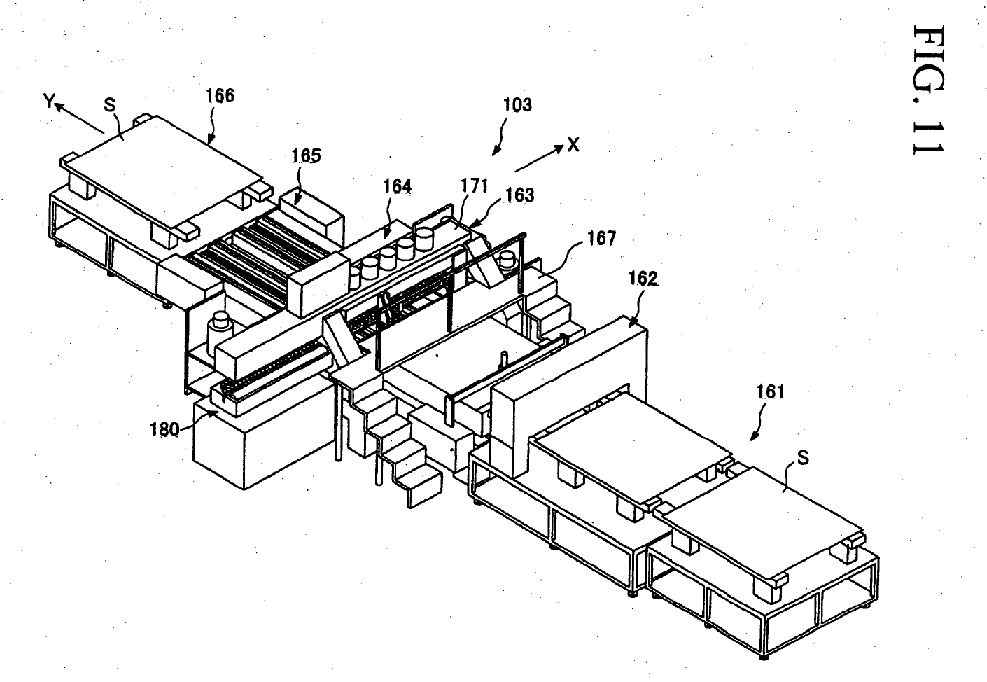

FIG. 11 is a perspective view showing the CF protective film formation device relating to Embodiment 4. The CF protective film formation device 103 is aligned from upstream to downstream (in the direction of arrow Y in FIG. 11), and includes a substrate supply part 161, a surface modification part 162, a patterning part 163, an inspection part 164, a dryer 165, and a substrate removal part 166, as shown in FIG. 1. Broadly described, the substrate S on which the color filter supplied from the substrate supply part 161 is formed undergoes a lyophilic treatment in the surface modification part 162. The protective film material described in the above-mentioned embodiments is then discharged and formed into a pattern on the surface of the color filter in the patterning part 163. Next, the patterned state is inspected in the inspection part 164, the protective film material is dried in the dryer 165, and the patterned substrate is removed by the substrate removal part 166. The parts 161 through 166 in this apparatus are arranged in a straight line along the movement of the substrate S. Since this apparatus 3 is a large device that can treat large substrates, a walkway 67 is provided to allow workers to perform maintenance on the head unit, to be later described.

The substrate supply part 161 and the substrate removal part 166 can be configured from the desired substrate transportation device, for which a roller conveyer, a belt conveyer, or the like, for example, may be used. The surface modification part 162 includes a plasma treatment chamber, and modifies the color filter surface coated with the protective film material in a manner that improves the wettability of the surface (hereinafter referred to as lyophilization). The wettability of the surface of the color filter by the protective film material is improved by this surface modification treatment. An oxygen plasma treatment (O₂ plasma treatment), with the oxygen in the atmosphere as a reactant gas, may be used as the surface modification treatment in Embodiment 4 to lyophilize the color filter surface. In addition to oxygen plasma treatment, lyophilization treatment that uses a UB lamp can also be used to lyophilize the color filter surface.

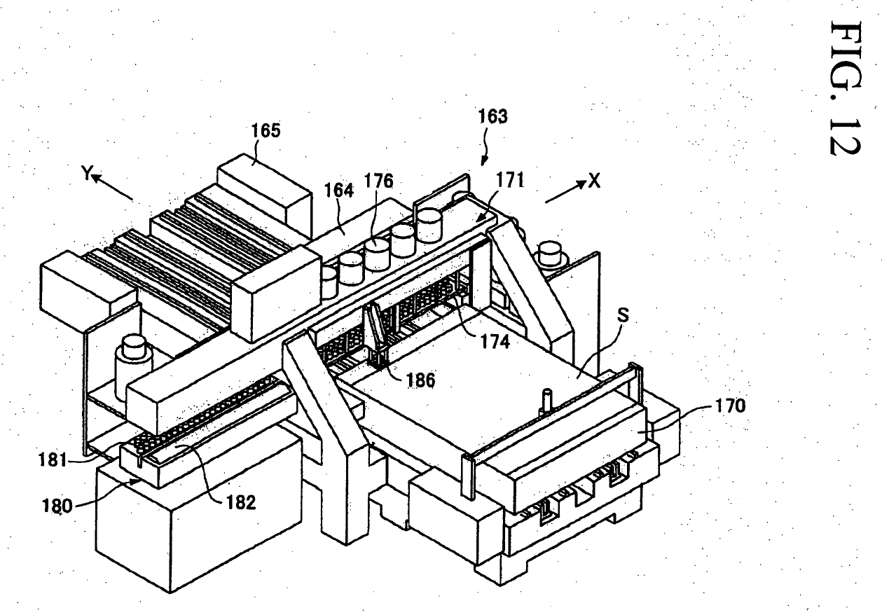

FIG. 12 is a schematic structural perspective view showing the vicinity of the patterning part. The patterning part 163 forms a CF protective film on the color filter surface by discharging the protective film material in liquid form onto the color filter surface of the substrate S on which the color filter is already formed. As shown in FIG. 12, the substrate S on which the color filter is already formed is held by adhesion on a stage 170 capable of moving in one direction (the direction indicated by arrow Y in FIG. 12), and the substrate S is configured to be transported in one direction (from the right side to the left side in FIG. 12) in this state. In the patterning part 163, a head unit 171 extending in the direction perpendicular to the direction of transportation of the substrate S (the X direction in FIG. 12) is mounted on the main body of the apparatus. Specifically, the patterning part 163 of the present embodiment is configured such that the substrate S alone moves while the droplet discharge head remains stationary. The head unit 171 includes a large standard plate 174 with a plurality of mounted droplet discharge heads 134 that are aligned in the direction perpendicular to the direction of transportation of the substrate S.

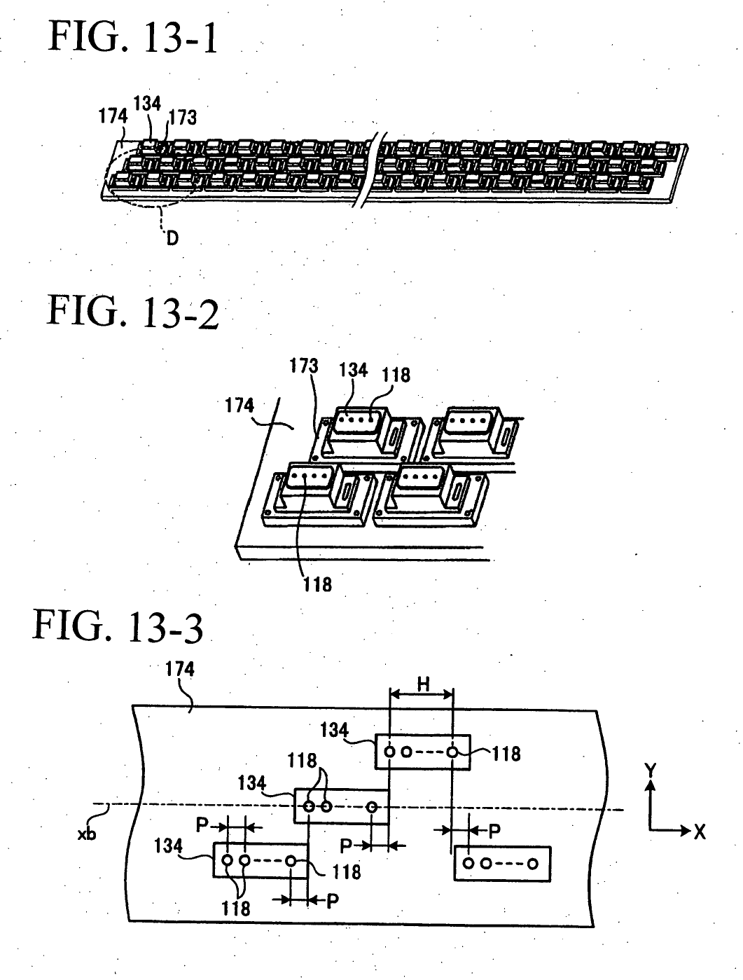

FIG. 13-1 is a perspective view of a large standard plate as seen from the nozzle of the droplet discharge head, and FIG. 13-2 is an enlarged view of a single droplet discharge head (enlarged view of the circle indicated by symbol D in FIG. 13-1). FIG. 13-3 is a plan view of a droplet discharge head as seen from the nozzle. As seen in these diagrams, a single droplet discharge head 134 is fixed per small standard plate 73, and several small standard plates 73 with the heads are fixed to a single large standard plate 174. In the present embodiment, the plurality of droplet discharge heads 134 is arranged in three rows of multiple heads each, and the rows are staggered in relation to each other in the longitudinal direction of the large standard plate 174. Each droplet discharge head 134 also has a plurality of nozzles 118 (discharge outlets, FIG. 13-3). If the number of nozzles 118 in a droplet discharge head 134 is n and the pitch between the nozzles 118 is P, then the distance between the nozzles 118 disposed at both ends of the row of nozzles in a droplet discharge head 134 is (n−1)×P. This is referred to as the nozzle alignment width and is expressed as H((n−1)×P).

As shown in FIG. 13-3, the plurality of nozzles 118 in the droplet discharge heads 134 is arranged virtually parallel to the longitudinal direction of the large standard plate 174, or, specifically, the X direction in FIG. 13-3. The diagonally adjacent droplet discharge heads 134 are disposed such that the interval between the nozzles 118 located at adjacent ends is equal to the nozzle pitch P. Thus, the patterning length of the patterning part 163 in the X direction is H×m, which is the nozzle alignment width H multiplied by the total number m of droplet discharge heads 134 in the large standard plate 174.

With this configuration, the head unit 171 is capable of discharging droplets of the protective film material at a specific pitch P over a considerable distance of several m, for example, in the longitudinal direction of the large standard plate 174, or, specifically, the direction perpendicular to the direction in which the substrate S is transported. A red protective film material can then be deposited in the desired pattern configuration over the entire surface of the substrate S by discharging droplets of the protective film material while transporting the substrate S in the direction perpendicular to the direction of alignment of the droplet discharge heads 134. Thus, production efficiency is extremely high because a CF protective film can be formed on the color filter while transporting a substrate S with large dimensions in the direction perpendicular to the direction of transportation. Also, tilting the axis xb of the large standard plate 174 parallel to the direction of alignment of the nozzles 118 makes it possible to vary the apparent pitch between the nozzles 118. Thus, it is possible to adapt this apparatus to a plurality of conditions with different patterning pitches. The structural element denoted by the symbol 176 in FIG. 12 is a protective film material tank. The protective film material tank 176 contains the protective film material in liquid form, and supplies the protective film material to the droplet discharge heads 134 via piping (not shown).

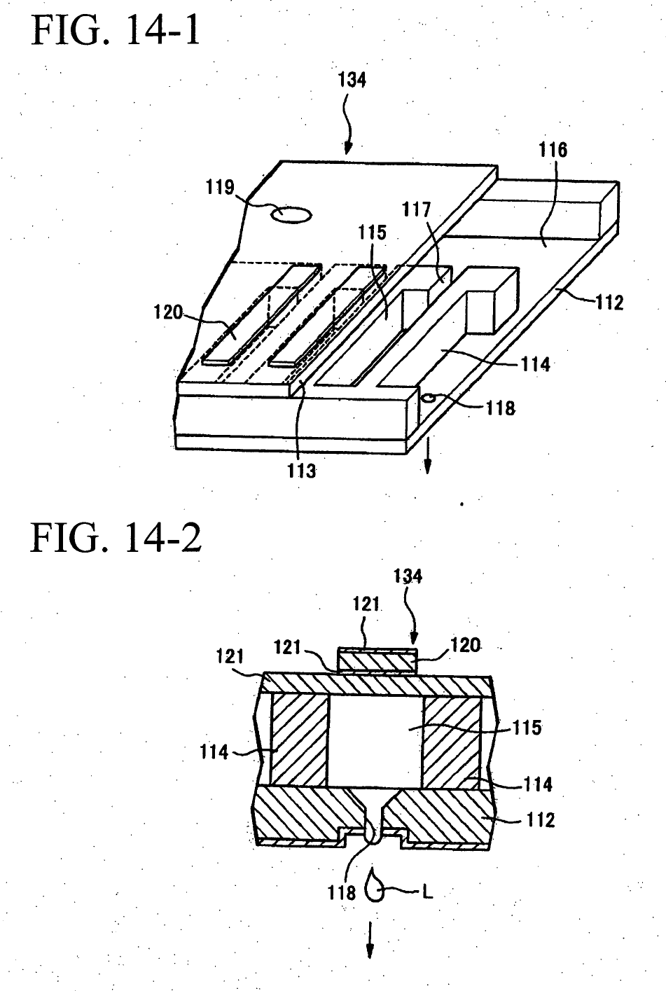

FIG. 14-1 is a perspective view showing the internal structure of a droplet discharge head. FIG. 14-2 is a cross-sectional view showing the internal structure of a droplet discharge head. In the droplet discharge heads 134, the liquid chamber is compressed by a piezoelement, for example, and the liquid is discharged by the resulting pressure waves, as described above. The droplet discharge heads 134 have a plurality of nozzles arranged in a single row or a plurality of rows. To describe one example of the structure of the droplet discharge heads 134, the droplet discharge heads 134 include, for example, a stainless nozzle plate 112 and an oscillating plate 113, and these are joined via dividing members (reservoir plates) 114, as shown in FIG. 14-1. A plurality of spaces 115 and a fluid collector 116 are formed by the dividing members 114 between the nozzle plate 112 and the oscillating plate 113. The spaces 115 and the fluid collector 116 are filled up with the protective film material, and the spaces 115 and fluid collector 116 are communicated via a supply outlet 117. Also, nozzles 118 to spray the protective film material from the spaces 115 are formed in the nozzle plate 112. A hole 119 to supply the protective film material to the fluid collector 116 is formed in the oscillating plate 113.

Also, piezoelectric elements (piezoelements) 120 are joined to the top surface opposite the surface facing the spaces 115 on the oscillating plate 113, as shown in FIG. 14-2. The piezoelectric elements 120 are located between a pair of electrodes 121 and are configured to protrude outward and to bend when supplied with an electric current. The oscillating plate 113 to which the piezoelectric elements 120 are joined in such a configuration is designed to bend simultaneously outward integrally with the piezoelectric elements 120, whereby the capacity of the spaces 115 increases. Therefore, the amount of protective film material corresponding to the increased capacity in the spaces 115 flows from the fluid collector 116 via the supply outlet 117. The piezoelectric elements 120 and the oscillating plate 113 return from this state to their original configuration when the current supplied to the piezoelectric elements 120 is terminated. Thus, the spaces 115 also return to their original capacity, so the pressure of the protective film material in the spaces 115 increases and droplets L of the protective film material are discharged from the nozzles 118 onto the substrate.

It is preferable to apply the fluid repellent treatment to at least the surface of the nozzle plate 112 on which the droplets L are discharged. Specifically, the angle of contact between the protective film material and the nozzle plate 112 is set to 50 degrees or greater, and preferably 80 degrees or greater. This is accomplished, for example, by coating the aforementioned surface of the nozzle plate 112 with a fluorine-containing silane-coupling agent. Applying the fluid repellent treatment to at least the aforementioned surface of the nozzle plate 112 makes it possible to reduce misalignment of the locations in which the droplets of the protective film material discharged from the nozzles 118 come into contact with the surface, and to obtain a homogeneous protective film. A system other than the piezo-jet type with the piezoelectric elements 120 may be used as the inkjet system for the droplet discharge heads 134; for example, a system that uses an electrothermal converter as an energy-producing element may be employed.

A suctioning/cleaning part 180 is provided along the longitudinal direction of the head unit 171, as shown in FIG. 12. The suctioning/cleaning part 180 is intended to prevent discharge failures due to clogging of the droplet discharge heads 134 and the like, and to perform suction/cleaning operations on the droplet discharge heads 134 at a specific frequency. In a specific configuration, the suctioning/cleaning part 180 is provided with a capping unit 81 to stopper the nozzles in the droplet discharge heads 134 during suction, and a wire 82 to wipe the nozzles and the area around the nozzles. Also, a detector 164 to detect the patterned state of the patterned substrate S, or, specifically, whether the droplets of the protective film material have stably been discharged to their specific locations, is provided downstream of the head unit 171.

The detector 164 is configured from a line sensor that uses a CCD or the like, for example.

Furthermore, in the present embodiment, a correction head 186 is installed upstream of the head unit 171, and the head corrects failed spots by discharging the protective film material a second time only onto certain spots when the detector 164 discovers failed spots in which the protective film material has not been discharged to specific locations. Since the correction head 186 is located upstream of the head unit 171, the stage 170 moves in the opposite direction (from the left side to the right side in FIG. 3) only during correction. The correction head 186 has only one droplet discharge head 134 and is capable of moving in the direction perpendicular to the direction in which the substrate S is transported. Alternatively, the correction head 186 may also be located downstream of the head unit 171, in which case there is no need for the stage 170 to move in the opposite direction. Also, a dryer 165 that uses a laser drying system, for example, is provided downstream of the detector 164. The dryer 165 is not limited to this system alone, and heating may be performed with a hot plate, an infrared heater, or in an oven.

The configuration of the CF protective film formation device 103 was described above, but a washing part may also be provided upstream of the surface modification part 162 of the CF protective film formation device 103. The CF protective film formation device 103 is supplied with a substrate S on which a color filter is formed, and can also be configured such that the substrate S is washed in the washing part by wet washing, ozone washing, or other such methods prior to the surface modification of the substrate S, and the cleaned substrate S is then supplied to the surface modification part 162. With this configuration, it is possible to reduce the occurrence of patterning failures resulting from impurities or other matter adhering to the surface of the color filter formed on the substrate S, and to improve the yield rate.

The CF protective film formation device 103 of the present embodiment includes a patterning part 163 in the middle of the rectilinear substrate transportation line between the substrate supply part 161 and the substrate removal part 166, and forms a pattern with the desired configuration by discharging the protective film material from the droplet discharge heads 134 while moving the substrate S in a direction that intersects the direction in which the plurality of droplet discharge heads 134 is aligned. In other words, the configuration is such that the substrate S on which the CF protective film has not yet been formed is fed from one end of the patterning part 163, and the substrate S on which the CF protective film has already been formed is removed from the other end of the patterning part 163.

Thus, the substrate S can be run continuously through the patterning part 163, and patterning can be performed without interruption using a plurality of droplet discharge heads 134 during unidirectional transportation. Therefore, the tact time required to process one substrate can be reduced and an apparatus that is more productive can be designed in comparison with a conventional apparatus in which the substrates S are drawn one at a time from the transportation line and into the CF protective film formation device. Also, the substrate supply part 161, the patterning part 163, and the substrate removal part 166 are arranged in a straight line, making it possible to reduce the space occupied by the apparatus in comparison with a conventional apparatus in which a coloring device is disposed next to the transportation line. Furthermore, the configuration of the apparatus can be simplified because there is no need for a transportation device whose function is to change the direction in which untreated substrates are transported, as in a conventional apparatus.

Also, the substrate surface can be subjected to a lyophilic treatment or fluid repellent treatment before the protective film material is discharged, and the protective film material can be stably discharged onto the desired areas on the substrate because the patterning part 163 is provided with the surface modification part 162. It is therefore possible to reduce the occurrence of patterning failures wherein the protective film material is applied to areas other than the desired areas or wherein the desired areas are not sufficiently wetted by the protective film material, and the yield rate can be improved. Also, the protective film material discharged onto the substrate after patterning can be dried because the dryer 165 is provided downstream of the patterning part 163. Thus, when a different type of liquid materials is discharged in the next step, it is possible to prevent the liquid materials from mixing. It is also possible to determine the presence of patterning failures and to distinguish between satisfactory and unsatisfactory substrates onto which the protective film material has been discharged because a detector 164 to detect the patterned state is provided. Depending on the circumstances, unsatisfactory substrates can be subjected to corrective operations.

The specific configuration of the smaller parts of the droplet discharge device or the CF protective film formation device relating to the above-mentioned embodiments can be modified as necessary. In the above-mentioned embodiments, examples were given wherein the method for manufacturing an electro-optical panel relating to the present invention was applied to the formation of a CF protective film, but the present invention is not limited by CF protective films alone and may be adapted for forming color filters as such, orientation films, injected liquid crystals, organic EL elements, and other devices, or the formation of thin films or fine patterns with various wiring formation techniques.

(Object of Application)

In addition to portable phones, examples of electronic devices to which the electro-optical panel relating to the present invention can be applied include portable information devices known as PDAs (personal digital assistants), portable personal computers, personal computers, digital still cameras, in-vehicle monitors, digital video cameras, liquid crystal televisions, tape recorders with viewfinders and direct-view tape recorders with monitors, car navigation devices, pagers, electronic notebooks, calculators, word processors, workstations, video telephones, POS terminals, and other devices that use electro-optical panels as electro-optical devices. Therefore, it is apparent that the present invention can also be applied to the electrically connected structures in these electronic devices.

Also, the electro-optical panel may be a transparent or reflective electro-optical panel, and may use an illuminating device (not shown) as a backlight. The same applies to an active-matrix color electro-optical panel. For example, examples of passive-matrix electro-optical panels were given in the embodiments described above, but an active-matrix electro-optical panel (for example, an electro-optical panel containing a TFT (thin film transistor) or TFD (thin film diode) as a switching element) can similarly be used in the electro-optical device of the present invention. The present invention can not only be adapted to a liquid crystal display device as such an electro-optical panel, but can also be similarly used in various electro-optical devices in which the display state can be controlled for each of a plurality of pixels, such as an organic electroluminescence device, an inorganic electroluminescence device, a plasma display device, an electrophoretic display device, a field emission display device, an LED (light-emitting diode) display device, or the like. Particularly, a full color display is made possible with an electroluminescence device (organic, inorganic) by emitting white light and placing a color filter on the front surface of the device.

(Effects of the Embodiments)

With the proposed method for manufacturing an electro-optical panel, the viscosity and surface tension of the protective film material are adjusted to within the above-mentioned specific ranges. Thus, there are no discharge failures due to nozzle clogging or the like, and it is possible to discharge droplets of the protective film material from the nozzles in a stable manner. Furthermore, the amount of the protective film material used can be reduced compared with conventional spin coating because a color filter protective film is formed using a droplet discharge system. Furthermore, since there is no need to set up a separate step for washing the back surface of the color filter substrate, the time for manufacturing the electro-optical panel can be shortened, and there is also no need for a cleaning solution.

In this method for manufacturing an electro-optical panel, the angle of contact of the protective film material on the flat member (nozzle plate) is 30 degrees or greater and 70 degrees or less. Thus, it is possible to suppress excessive wetting of the protective film material in the nozzle plate and to discharge the droplets in a more precise direction. Stable discharge is also possible.

Also, the boiling point of the solvent is 180° C. or greater and 300° C. or less. The protective film material does not immediately dry when applied to a color filter substrate because a solvent with a high boiling point is slow to dry. If the boiling point of the solvent in the protective film material is within the above-mentioned range, sufficient time can be ensured for the thickness of the protective film material to become uniform on the color filter substrate. Thus, the film thickness of the color filter protective film can be made uniform. Furthermore, nozzle clogging due to the precipitation of solids near the nozzles can be prevented.

The temperature for drying the protective film material is 70° C. or less, and the drying time is 5 minutes or greater. It is preferable to volatize the solvent in an amount of time that allows for a relatively low temperature in order to smooth the surface of the color filter protective film, but the surface of the color filter protective film can still be smoothed if these ranges are observed. Thus, it is possible to prevent breaking of the ITO or rupturing of the orientation film formed on the color filter protective film.

Also, the film thickness of the protective film material after the drying step is controlled by varying the interval between the droplets of the protective film material discharged on the color filter and/or the mass of the droplets. Thus, the film thickness of the color filter protective film can be easily controlled if the same type of protective film material is used.

The protective film material is applied to the entire surface of the matrix on which the color filter is formed. Thus, it is easier to form a color filter protective film with uniform thickness on a chip with smaller dimensions.

Also, the protective film material may be applied solely to the chip on the matrix on which the color filter is formed. Thus, there is less wasting of the protective film material because the protective film material can be applied to the necessary areas alone.

The terms “front,” “back, “up,” “down,” “perpendicular,” “horizontal,” “diagonal,” and other direction-related terms used above indicate the directions in the diagrams used herein. Therefore, the direction-related terms used to describe the present invention should be interpreted in relative terms as applied to the diagrams used.

“Substantially,” “essentially,” “about,” and other approximation-indicating terms used above represent a reasonable amount of deviation that does not bring about a considerable change as a result. Terms that represent these approximations should be interpreted so as to include an error of about ±5% at least, as long as there is no considerable change due to the deviation.

The entire disclosures in Japanese Patent Application Nos. 2003-068330 and 2004-040067 are incorporated in this specification by reference.

The embodiments described above constitute some of the possible embodiments of the present invention, and it is apparent to those skilled in the art that it is possible to add modifications to the above-described embodiments by using the above-described disclosure without exceeding the range of the present invention as defined in the claims. The above-described embodiments furthermore do not limit the range of the present invention, which is defined by the accompanying claims or equivalents thereof, and are only designed to provide a description of the present invention.

1. A method for manufacturing an electro-optical panel, comprising:
a filter formation step for forming a color filter on a substrate;
a surface modification step for modifying the surface of said color filter;
a protective film material application step for discharging and applying droplets of a protective film material containing a resin and a solvent onto said color filter, viscosity of said protective film material at 20° C. being 1 to 20 mPa.s, and a surface tension at 20° C. being 20 to 70 mN/m; and
a protective film formation step for drying said solvent and forming a color filter protective film for protecting said color filter.

2. The manufacturing method according to claim 1, wherein said surface modification step includes emission of ultraviolet light from a UV lamp 3.

3. The manufacturing method according to claim 1, wherein said viscosity of said protective film material at 20° C. is 4 to 8 mPa.s, and said surface tension at 20° C. is 25 to 35 mN/m.

4. The manufacturing method according to claim 3, wherein the boiling point of said solvent is 180° C. or greater and 300° C. or less.

5. The manufacturing method according to claim 4, wherein the boiling point of said solvent is 200° C. or greater.

6. The manufacturing method according to claim 1, wherein said resin contains at least one compound selected from the group consisting of acrylic resin, epoxy resin, imide resin, and fluorine resin.

7. The manufacturing method according to claim 6, wherein said solvent contains at least one compound selected from the group consisting of glycerin, diethylene glycol, methanol, ethanol, water, 1,3-dimethyl-2-imidazolidinone, ethoxyethanol, N,N-dimethyl formamide, N-methyl-2-pyrrolidone, ethylene glycol monomethyl ether acetate, propylene glycol monomethyl ether acetate, ethyl lactate, 3-methoxy methyl propionate, 3-ethoxy ethyl propionate, butyl acetate, 2-heptanone, propylene glycol monomethyl ether, γ-butyrolactone, diethylene acetate glycol monobutyl ether, diethylene glycol methyl ether, and diethylene glycol methylethyl ether.

8. The manufacturing method according to claim 7, wherein said solvent is diethylene acetate glycol monobutyl ether.

9. The manufacturing method according to claim 1, wherein said protective film material application step includes the discharge of droplets of said protective film material from nozzles formed on a flat member, and an angle of contact of said protective film material on said flat member is 30 degrees or greater and 170 degrees or less.

10. The manufacturing method according to claim 9, wherein said flat member is coated with a fluorine-containing silane-coupling agent.

11. The manufacturing method according to claim 10, wherein said silane-coupling agent comprises trifluoropropyl trichlorosilane.

12. The manufacturing method according to claim 9, wherein said protective film material application step includes controlling the amount of application by varying the interval between droplets of said protective film material discharged on said color filter, and/or the mass of droplets.

13. The manufacturing method according to claim 12, wherein said protective film material application step includes the application of said protective film material on an entire surface of said substrate.

14. The manufacturing method according to claim 9, wherein said angle of contact of said protective film material on said color filter in said protective film material application step is 10 degrees or less.

15. The manufacturing method according to claim 9, wherein droplet discharge is performed by ink jetting in said protective film material application step.

16. The manufacturing method according to claim 1, wherein a drying temperature in said protective film formation step is 70° C. or greater, and a drying time is 5 minutes or greater.

17. The manufacturing method according to claim 16, wherein said drying temperature in said protective film formation step is 50° C. or less, and said drying time is 10 minutes or greater.

18. The manufacturing method according to claim 17, wherein said drying temperature in said protective film formation step is 30° C. or less, and said drying time is one hour or more.

19. The manufacturing method according to claim 1, further comprising a step for mounting surface-mounted components on said substrate after said protective film formation step.

20. A color filter protective film material for an electro-optical panel comprising a resin and a solvent, having viscosity at 20° C. being 1 to 20 mPa.s and a surface tension at 20° C. being 20 to 70 mN/m.

21. The protective film material according to claim 20, wherein said viscosity at 20° C. is 4 to 8 mPa.s, and said surface tension at 20° C. is 25 to 35 mN/m.

22. The protective film material according to claim 21, wherein a boiling point of said solvent is 180° C. or greater and 300° C. or less.

23. The protective film material according to claim 22, wherein said boiling point of said solvent is 200° C. or greater.

24. The protective film material according to claim 20, wherein said resin contains at least one compound selected from the group consisting of acrylic resin, epoxy resin, imide resin, and fluorine resin.

25. The protective film material according to claim 24, wherein said solvent contains at least one compound selected from the group consisting of glycerin, diethylene glycol, methanol, ethanol, water, 1,3-dimethyl-2-imidazolidinone, ethoxyethanol, N,N-dimethyl formamide, N-methyl-2-pyrrolidone, ethylene glycol monomethyl ether acetate, propylene glycol monomethyl ether acetate, ethyl lactate, 3-methoxy methyl propionate, 3-ethoxy ethyl propionate, butyl acetate, 2-heptanone, propylene glycol monomethyl ether, γ-butyrolactone, diethylene acetate glycol monobutyl ether, diethylene glycol methyl ether, and diethylene glycol methylethyl ether.

26. The protective film material according to claim 25, wherein said solvent is diethylene acetate glycol monobutyl ether.

27. An electro-optical panel formed by a method comprising:
a filter formation step for forming a color filter on a substrate;
a surface modification step for modifying a surface of said color filter;
a protective film material application step for discharging and applying droplets of a protective film material containing a resin and a solvent onto said color filter, a viscosity of said protective film material at 20° C. being 1 to 20 mPa.s, and a surface tension at 20° C. being 20 to 70 mN/m; and
a protective film formation step for drying said solvent and forming a color filter protective film for protecting said color filter.
